(19) United States
(12) Patent Application Publication
(10) Pub. No.: US 2025/0199396 A1
(43) Pub. Date: Jun. 19, 2025

(54) METHOD FOR MANUFACTURING PELLICLE FOR FORMING METAL SILICIDE CAPPING LAYER AND PELLICLE MANUFACTURED THEREFROM

(71) Applicant: DNF CO., LTD., Daejeon (KR)

(72) Inventors: Sangyong JEON, Daejeon (KR); Taeseok BYUN, Daejeon (KR); Yonghee KWONE, Daejeon (KR); Sangchan LEE, Daejeon (KR); Youngjae IM, Daejeon (KR); Sangick LEE, Daejeon (KR)

(21) Appl. No.: 18/851,623

(22) PCT Filed: Mar. 24, 2023
(86) PCT No.: PCT/KR2023/003950

§ 371 Date: Sep. 26, 2024

(30) Foreign Application Priority Data
Apr. 14, 2022 (KR) 10-2022-0046141

(51) Int. Cl. G03F 1/62; C23C 16/42; C23C 16/455

(52) U.S. Cl. CPC G03F 1/62; C23C 16/42; C23C 16/45553; C23C 16/45555

(57) ABSTRACT

The present invention provides a method for manufacturing a pellicle and a pellicle for extreme ultraviolet exposure manufactured by the method, the method comprising a step of forming a metal silicide capping layer by using a silicon precursor and a metal precursor, wherein the pellicle can exhibit excellent performance in terms of transmittance and thermal emissivity.

### TECHNICAL FIELD

The present invention relates to a method for manufacturing a pellicle for forming a metal silicide capping layer using a silicon precursor and a metal precursor, and a pellicle for extreme ultraviolet (EUV) lithography manufactured therefrom.

### BACKGROUND ART

In a lithography process, which is one of the main processes of semiconductor manufacturing, a wavelength of a light source is important to make a mask circuit finer and clearer, and the smaller the wavelength, the higher the resolution, such that a finer circuit pattern may be drawn and a small-sized semiconductor device may be produced. Recently, a light source used in the lithography process has been developed to be the range of extreme ultraviolet (EUV) having a wavelength of 13.5 nm.

In the case of the lithography process using an EUV light source, since a circuit of a mask is drawn on a wafer in a reduced size, when the mask is contaminated with impurities such as dust or foreign matter, light is absorbed or reflected due to these impurities, which causes damage to the transferred pattern and a significant decrease in production yield of semiconductor products. In order to prevent impurities from adhering to a surface of the mask, a thin film called a pellicle is covered on the mask for protection. The need for such a pellicle has increased because it is essential in terms of yield and at the same time it serves to extend the lifespan of the mask.

In the EUV lithography process, the light source passes through the pellicle twice. Therefore, in order to reduce a loss of the light source passing through the pellicle, a pellicle material having a transmittance of 90% or more has been required, and many studies have been conducted. In addition, when the EUV light source passes through the pellicle, the pellicle is instantly heated to 600 to 1,200° C. and then cooled to room temperature. Accordingly, a material having sufficient thermal emissivity should be applied to withstand such thermal shock. Therefore, there is a need for studies on a pellicle having more excellent transmittance and thermal emissivity.

### DISCLOSURE

### Technical Problem

An embodiment of the present invention is directed to providing a method for manufacturing a pellicle for extreme ultraviolet (EUV) lithography for forming a metal silicide capping layer on a core layer using a silicon precursor and a metal precursor.

Another embodiment of the present invention is directed to providing a pellicle having excellent transmittance and thermal emissivity that is manufactured by the above manufacturing method and includes a metal silicide capping layer.

### Technical Solution

In one general aspect, a method for manufacturing a pellicle includes forming a metal silicide capping layer on a core layer using a silicon precursor represented by the following Chemical Formula 1 and a metal precursor:

SiHₙX₄₋ₙ Chemical Formula 1
in Chemical Formula 1,
X is halogen; and
n is an integer of 1 to 3.

The core layer may be a layer formed of Si, SiNₓ, SiCₓ, or a mixture thereof, and may have a two-layer structure in which a Si layer and a SiNₓ layer are sequentially stacked.

The pellicle may include one or more protective layers formed at a position interposed between the core layer and the capping layer, a position under the core layer, or both the positions, and the protective layer may be formed of one or two or more materials selected from BₓN, B, Zr, Zn, BₓC, SiCₓ, and SiNₓ.

According to an exemplary embodiment of the present invention, a metal of the metal precursor may be Mo, Ni, Ru, Pt, Cu, Ti, Zr, Nb, Hf, Ta, W, or Cr, and a molar ratio of metal: silicon in the metal precursor and the silicon precursor may be 1:0.2 to 6.

According to an exemplary embodiment of the present invention, the forming of the metal silicide capping layer may be performed by atomic layer deposition (ALD) or chemical vapor deposition (CVD).

According to an exemplary embodiment of the present invention, the forming of the metal silicide capping layer may include:
a) raising a temperature of the core layer mounted in a chamber;
b) adsorbing the silicon precursor and the metal precursor onto the core layer; and
c) manufacturing a metal silicide capping layer by feeding a reaction gas into the core layer onto which the silicon precursor and the metal precursor are adsorbed.

The reaction gas may be one or two or more selected from oxygen (O₂), ozone (O₃), distilled water (H₂O), hydrogen peroxide (H₂O₂), nitrogen monoxide (NO), nitrous oxide (N₂O), nitrogen dioxide (NO₂), ammonia (NH₃), nitrogen (N₂), hydrazine (N₂H₄), an amine, a diamine, carbon monoxide (CO), carbon dioxide (CO₂), a C1 to C12 saturated or unsaturated hydrocarbon, hydrogen (H₂), argon (Ar), and helium (He).

In another general aspect, a pellicle includes: a core layer; and a metal silicide capping layer formed on the core layer and manufactured using a silicon precursor represented by the following Chemical Formula 1 and a metal precursor:

SiHₙX₄₋ₙ Chemical Formula 1
in Chemical Formula 1,
X is halogen; and
n is an integer of 1 to 3.

According to an exemplary embodiment of the present invention, a molar ratio of metal:silicon in the metal silicide capping layer may be 1:0.2 to 6.

### Advantageous Effects

The present invention provides a method for manufacturing a pellicle for EUV lithography for forming a metal silicide capping layer using a silicon precursor and a metal precursor, and a pellicle manufactured by the manufacturing method, and the pellicle has excellent transmittance and thermal emissivity.

### DESCRIPTION OF DRAWINGS

FIG. 1 is a schematic view illustrating a structure and manufacturing process of a pellicle of the present invention.

FIG. 2 is a view illustrating a deposition rate of a metal silicide capping layer according to Example 1 of the present invention.

FIG. 3 is a view illustrating a molar ratio of silicon to a metal in the metal silicide capping layer according to Example 1 of the present invention.

### BEST MODE

The present invention provides a method for manufacturing a pellicle for extreme ultraviolet (EUV) lithography that includes a metal silicide capping layer manufactured using a silicon precursor and a metal precursor, and a pellicle manufactured therefrom.

Unless the context clearly indicates otherwise, singular forms used in the present invention may be intended to include plural forms.

In addition, a numerical range used in the present invention includes upper and lower limits and all values within these limits, increments logically derived from a form and span of a defined range, all double limited values, and all possible combinations of the upper and lower limits in the numerical range defined in different forms. Unless otherwise specifically defined in the specification of the present invention, values out of the numerical range that may occur due to experimental errors or rounded values also fall within the defined numerical range.

The expression “comprise(s)” described in the present invention is intended to be an open-ended transitional phrase having an equivalent meaning to “include(s)”, “contain(s)”, “have (has)”, and “are (is) characterized by”, and does not exclude elements, materials, or steps, all of which are not further recited herein.

The term “halogen” described in the present invention refers to fluorine, chlorine, bromine, or iodine.

Hereinafter, the present invention will be described in detail. However, unless otherwise defined, all the technical terms and scientific terms used herein have the same meanings as commonly understood by those skilled in the art to which the present invention pertains, and descriptions for the known function and configuration unnecessarily obscuring the gist of the present invention will be omitted in the following descriptions.

The present invention provides a method for manufacturing a pellicle, the method including forming a metal silicide capping layer on a core layer using a silicon precursor represented by the following Chemical Formula 1 and a metal precursor:

SiHₙX₄₋ₙ Chemical Formula 1
in Chemical Formula 1,
X is halogen; and
n is an integer of 1 to 3.

The core layer may be a layer formed of Si, SiNₓ, SiCₓ, or a mixture thereof, and may have a two-layer structure in which a Si layer and a SiNₓ layer are sequentially stacked.

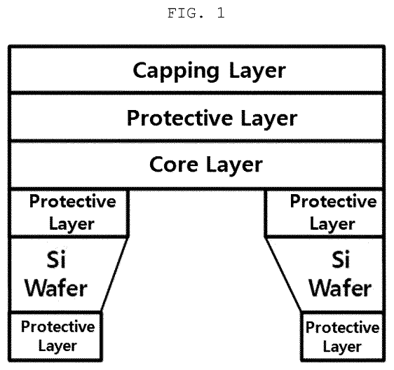

The pellicle may include a core layer, a capping layer, and a protective layer as illustrated in the schematic view of FIG. 1. The pellicle has a transmittance to EUV exposure light of 85% or more, and a reflectivity to EUV exposure light of the pellicle is preferably within 0.04%.

Si constituting the core layer may be silicon including one or more states of single crystal, polycrystal, and amorphous states. Since the SiNₓ material has higher mechanical strength and higher chemical stability than the Si material, when the SiNₓ layer is formed on the Si layer in the core layer, the mechanical strength and the chemical stability of the core layer may be secured.

The core layer preferably has a transmittance to EUV exposure light of 85% or more. In addition, the capping layer may be formed to have various thicknesses in consideration of mechanical strength and optical properties of the pellicle. Preferably, the capping layer may be formed to have a thickness that minimizes the reflectivity of the pellicle to EUV exposure light.

Preferably, the silicon precursor constituting the capping layer may be SiH₂X₂ or SiHX₃, and more specifically SiH₂X₂. Specifically, X in Chemical Formula 1 representing the silicon precursor may be chlorine, bromine, or iodine, and more specifically, X in Chemical Formula 1 may be chlorine or iodine, but is not limited thereto.

Since the metal silicide capping layer manufactured by the manufacturing method according to an exemplary embodiment of the present invention is manufactured in the form of a uniform thin film having a certain ratio of components according to the purpose, the metal silicide capping layer has improved thermal and mechanical durability, and thus has excellent light transmittance and thermal emissivity. Therefore, the metal silicide capping layer may be well suited for a pellicle used for EUV lithography.

According to an exemplary embodiment of the present invention, the pellicle may include one or more protective layers formed at a position interposed between the core layer and the capping layer, a portion under the core layer, or both the positions, and the protective layer may be formed of one or two or more materials selected from BₓN, B, Zr, Zn, BₓC, SiCₓ, and SiNₓ.

The protective layer may function to protect the capping layer from a chemical reaction occurring in an EUV lithography environment. In an environment where a pellicle is used, a large amount of hydrogen radicals exists, and these hydrogen radicals may react with the capping layer, resulting in deterioration of the function of the capping layer. Therefore, the protective layer may serve to protect the capping layer from being in contact with the hydrogen radicals, and may further serve to enhance mechanical strength of the pellicle.

According to an exemplary embodiment of the present invention, a metal of the metal precursor may be Mo, Ni, Ru, Pt, Cu, Ti, Zr, Nb, Hf, Ta, W, or Cr, specifically, Mo, Ni, Ti, Zr, Nb, Hf, or W, and more specifically, Mo, Ti, or W, and the metal precursor may be a metal halide, but is not limited thereto.

According to an exemplary embodiment of the present invention, a molar ratio of metal:silicon in the metal precursor and the silicon precursor may be 1:0.2 to 6, preferably 1:0.5 to 5.0, and more preferably 1:1.0 to 3.0.

In an exemplary embodiment of the present invention, a method for forming the metal silicide capping layer may be a conventional method used in the art, specifically, atomic layer deposition (ALD), chemical vapor deposition (CVD), metal organic chemical vapor deposition (MOCVD), low pressure chemical vapor deposition (LPCVD), plasma enhanced chemical vapor deposition (PECVD), or plasma enhanced atomic layer deposition (PEALD), preferably atomic layer deposition (ALD) or chemical vapor deposition (CVD), and more preferably atomic layer deposition (ALD).

According to an exemplary embodiment of the present invention, the method for forming the metal silicide capping layer may include: a) raising a temperature of the core layer mounted in a chamber; b) adsorbing the silicon precursor and the metal precursor onto the core layer; and c) manufacturing a metal silicide capping layer by feeding a reaction gas into the core layer onto which the silicon precursor and the metal precursor are adsorbed.

In addition, the method for forming the metal silicide capping layer according to an exemplary embodiment may further include, after the step b) and after the step c), purging the inside of the chamber with a carrier gas. The steps b) and c) may be repeatedly performed as one cycle.

In an exemplary embodiment, conditions of the formation method may be adjusted according to a desired structure or thermal characteristics of the capping layer, and examples of the conditions include an input flow rate of the silicon precursor, an input flow rate of the metal precursor, feeding flow rates of a reaction gas and a carrier gas, and RF power.

As a non-limiting example of these conditions, the conditions may be adjusted as follows: an input flow rates of the silicon precursor and the metal precursor of 1 to 1,000 sccm, a flow rate of carrier gas of 1 to 5,000 sccm, a flow rate of reaction gas of 10 to 5,000 sccm, a pressure of 0.1 to 10 torr, and a RF power of 10 to 1,000 W, but not limited thereto.

In an exemplary embodiment, the temperature of the core layer mounted in the chamber in the step a) may be raised to 200° C.˜700° C., and specifically, 300° C.˜500° C., but is not limited thereto.

The reaction gas may be one or two or more selected from oxygen (O₂), ozone (O₃), distilled water (H₂O), hydrogen peroxide (H₂O₂), nitrogen monoxide (NO), nitrous oxide (N₂O), nitrogen dioxide (NO₂), ammonia (NH₃), nitrogen (N₂), hydrazine (N₂H₄), an amine, a diamine, carbon monoxide (CO), carbon dioxide (CO₂), a C1 to C12 saturated or unsaturated hydrocarbon, hydrogen (H₂), argon (Ar), and helium (He).

Specifically, the reaction gas may be one or two or more selected from oxygen (O₂), hydrogen peroxide (H₂O₂), nitrous oxide (N₂O), ammonia (NH₃), nitrogen (N₂), and hydrogen (H₂), and more specifically, may be one or two or more selected from nitrous oxide (N₂O), ammonia (NH₃), and nitrogen (N₂), but is not limited thereto.

In an exemplary embodiment, the carrier gas is an inert gas, and may be one or two or more selected from argon (Ar), helium (He), and nitrogen (N₂), and specifically, argon (Ar), but is not limited thereto.

In an exemplary embodiment, a carrier gas and the silicon precursor are fed into the chamber, and then a purge process of removing an unadsorbed silicon precursor using the carrier gas may be performed. Subsequently, a carrier gas and the metal precursor are fed into the chamber, and then a purge process of removing an unadsorbed metal precursor using the carrier gas may be performed.

In an exemplary embodiment, a reaction gas is fed into the chamber, and then a purge process of removing reaction by-products and residual reaction gas using the carrier gas may be performed.

In an exemplary embodiment, the feeding of the silicon precursor, the purge process, the feeding of the metal precursor, the purge process, the feeding of the reaction gas, and the purge process may be repeatedly performed as one cycle.

According to an exemplary embodiment of the present invention, a growth thickness of the capping layer per cycle of the processes may be 1 to 4 Å, specifically, 1.3 to 3.7 Å, and more specifically, 1.6 to 3.3 Å.

The present invention provides a pellicle including: a core layer; and a metal silicide capping layer formed on the core layer and manufactured using a silicon precursor represented by the following Chemical Formula 1 and a metal precursor:

SiHₙX₄₋ₙ Chemical Formula 1
in Chemical Formula 1,
X is halogen; and
n is an integer of 1 to 3.

In an exemplary embodiment, the core layer may have a two-layer structure in which a Si layer and a SiNₓ layer are sequentially stacked, and a molar ratio of metal: silicon in the metal silicide capping layer may be 1:0.2 to 6, preferably 1:0.5 to 5.0, and more preferably 1:1.0 to 3.0.

The pellicle including the metal silicide capping layer formed on the core layer using a silicon precursor and a metal precursor according to an exemplary embodiment of the present invention has significantly improved transmittance and thermal emissivity, and thus may be used as a superior pellicle for EUV lithography.

Hereinafter, the method for manufacturing a pellicle for forming a metal silicide capping layer using a silicon precursor and a metal precursor, and a pellicle for EUV lithography manufactured therefrom according to the present invention will be described in more detail with reference to specific Examples.

However, the following Examples are only reference examples for describing the present invention in detail, and the present invention is not limited thereto and may be implemented in various forms. In addition, the terms used in the present invention are only to effectively describe specific Examples, but are not intended to limit the present invention.

### Example 1

A molybdenum silicide capping layer was formed by atomic layer deposition (ALD).

A silicon wafer, on which a silicon nitride thin film was formed and the molybdenum silicide capping layer was to be formed, was transferred to a deposition chamber and then maintained at 450° C. Diiodosilane (SiH₂I₂) filled in a stainless steel container was transferred to the deposition chamber using 50 sccm of argon gas as a carrier gas for 1 to 7 seconds, allowed to be adsorbed on the silicon wafer, and then unreacted compounds were removed for 3 seconds using 2,000 sccm of argon gas.

Next, molybdenum(V) chloride (MoCl₅) filled in a stainless steel container was transferred to the deposition chamber using 50 sccm of argon gas as a carrier gas for 1 second, allowed to be adsorbed on the silicon wafer, and then unreacted compounds were removed for 3 seconds using 2,000 sccm of argon gas. Thereafter, a molybdenum silicide capping layer was formed using 2,000 sccm of hydrogen gas and 100 W of plasma. Finally, unreacted compounds were removed for 3 seconds using 2,000 sccm of argon gas. The processes as described above were set as one cycle and 200 cycles were repeated, thereby forming a molybdenum silicide capping layer.

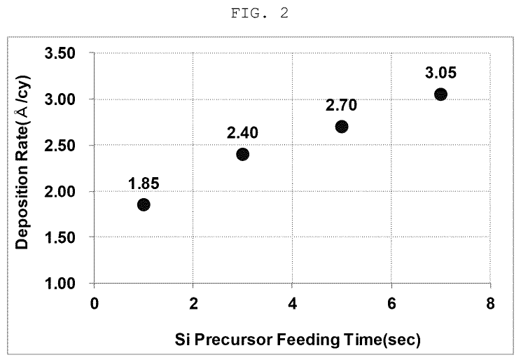

A thickness of the formed molybdenum silicide capping layer was measured through a scanning electron microscope, and it was confirmed that a growth thickness per cycle according to a feeding time of diiodosilane was 1.85 to 3.05 Å as illustrated in FIG. 2.

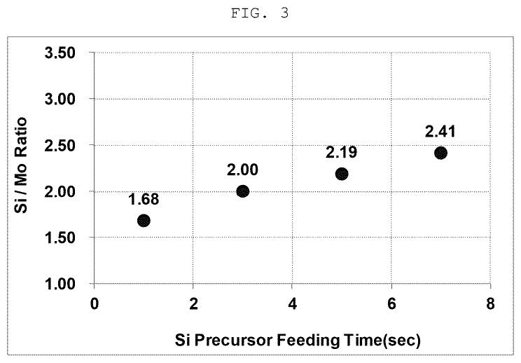

As a result of X-ray photoelectronic analysis of the deposited capping layer, it was confirmed that a ratio of silicon to molybdenum according to the feeding time of diiodosilane was 1.68 to 2.41 as illustrated in FIG. 3.

A crystal phase of the molybdenum silicide capping layer in which the ratio of silicon to molybdenum was 2 was analyzed by X-ray diffraction analysis. Before a heat treatment, the crystal phase was a hexagonal phase, but after the heat treatment, the crystal phase was a tetragonal phase, and thus it could be appreciated that a phase transition occurred.

As a result of analyzing the pellicle, to which the molybdenum silicide capping in which the ratio of silicon to molybdenum was 2 in the structure in which the silicon nitride thin film was provided as a core layer, was applied, it was confirmed that the transmittance was 92% and the reflectivity was 0.036.

### Example 2

A molybdenum silicide capping layer was formed by atomic layer deposition (ALD).

A silicon wafer, on which a silicon nitride thin film was formed and the molybdenum silicide capping layer was to be formed, was transferred to a deposition chamber and then maintained at 450° C. Dichlorosilane (SiH₂Cl₂) filled in a stainless steel container was transferred to the deposition chamber for 1 to 7 seconds through a mass flow controller (MFC) for adsorption onto the silicon wafer, and then unreacted compounds were removed for 3 seconds using 2,000 sccm of argon gas.

Next, molybdenum(V) chloride (MoCl₅) filled in a stainless steel container was transferred to the deposition chamber using 50 sccm of argon gas as a carrier gas for 1 second for adsorption onto the silicon wafer, and then unreacted compounds were removed for 3 seconds using 2,000 sccm of argon gas. Thereafter, a molybdenum silicide capping layer was formed using 2,000 sccm of hydrogen gas and 100 W of plasma. Finally, unreacted compounds were removed for 3 seconds using 2,000 sccm of argon gas.

The processes as described above were set as one cycle and 200 cycles were repeated, thereby forming a molybdenum silicide capping layer.

As a result of X-ray photoelectron analysis of the deposited capping layer, it was confirmed that a capping layer having a molar ratio of silicon to molybdenum of 2 could be obtained by controlling the feeding time of dichlorosilane.

### Example 3

A tungsten silicide capping layer was formed by atomic layer deposition (ALD).

A silicon wafer, on which a silicon nitride thin film was formed and the tungsten silicide capping layer was to be formed, was transferred to a deposition chamber and then maintained at 450° C. Diiodosilane (SiH₂I₂) filled in a stainless steel container was transferred to the deposition chamber using 50 sccm of argon gas as a carrier gas for 1 to 7 seconds for adsorption onto the silicon wafer, and then unreacted compounds were removed for 3 seconds using 2,000 sccm of argon gas.

Next, tungsten(V) chloride (WCl₅) filled in a stainless steel container was transferred to the deposition chamber using 50 sccm of argon gas as a carrier gas for 1 second for adsorption onto the silicon wafer, and then unreacted compounds were removed for 3 seconds using 2,000 sccm of argon gas. Thereafter, a tungsten silicide capping layer was formed using 2,000 sccm of hydrogen gas and 100 W of plasma. Finally, unreacted compounds were removed for 3 seconds using 2,000 sccm of argon gas.

The processes as described above were set as one cycle and 200 cycles were repeated, thereby forming a tungsten silicide capping layer.

As a result of X-ray photoelectron analysis of the deposited capping layer, it was confirmed that a tungsten silicide capping layer was formed.

Hereinabove, although the present invention has been described by specific matters and limited Examples and Comparative Examples, they have been provided only for assisting in the entire understanding of the present invention. Therefore, the present invention is not limited to the Examples. Various modifications and changes may be made by those skilled in the art to which the present invention pertains from this description.

Therefore, the spirit of the present invention should not be limited to the described Examples, but the claims and all modifications equal or equivalent to the claims are intended to fall within the spirit of the present invention.

1. A method for manufacturing a pellicle, comprising forming a metal silicide capping layer on a core layer using a silicon precursor represented by the following Chemical Formula 1 and a metal precursor:
SiHₙX₄₋ₙ Chemical Formula 1
in Chemical Formula 1,
X is halogen; and
n is an integer of 1 to 3.

2. The method of claim 1, wherein the core layer is a layer formed of Si, SiNₓ, SiCₓ, or a mixture thereof.

3. The method of claim 1, wherein the core layer has a two-layer structure in which a Si layer and a SiNₓ layer are sequentially stacked.

4. The method of claim 2, wherein the pellicle includes one or more protective layers formed at a position interposed between the core layer and the capping layer, a portion under the core layer, or both the positions, and the protective layer is formed of one or two or more materials selected from BₓN, B, Zr, Zn, BₓC, SiCₓ, and SiNₓ.

5. The method of claim 1, wherein a metal of the metal precursor is Mo, Ni, Ru, Pt, Cu, Ti, Zr, Nb, Hf, Ta, W, or Cr.

6. The method of claim 1, wherein a molar ratio of metal: silicon in the metal precursor and the silicon precursor is 1:0.2 to 6.

7. The method of claim 1, wherein the forming of the metal silicide capping layer is performed by atomic layer deposition (ALD) or chemical vapor deposition (CVD).

8. The method of claim 1, wherein the forming of the metal silicide capping layer includes:
a) raising a temperature of the core layer mounted in a chamber;
b) adsorbing the silicon precursor and the metal precursor onto the core layer; and
c) manufacturing a metal silicide capping layer by feeding a reaction gas into the core layer onto which the silicon precursor and the metal precursor are adsorbed.

9. The method of claim 8, wherein the reaction gas is one or two or more selected from oxygen (O₂), ozone (O₃), distilled water (H₂O), hydrogen peroxide (H₂O₂), nitrogen monoxide (NO), nitrous oxide (N₂O), nitrogen dioxide (NO₂), ammonia (NH₃), nitrogen (N₂), hydrazine (N₂H₄), an amine, a diamine, carbon monoxide (CO), carbon dioxide (CO₂), a C1 to C12 saturated or unsaturated hydrocarbon, hydrogen (H₂), argon (Ar), and helium (He).

10. A pellicle comprising:
a core layer; and
a metal silicide capping layer formed on the core layer and manufactured using a silicon precursor represented by the following Chemical Formula 1 and a metal precursor:
SiHₙX₄₋ₙ Chemical Formula 1
in Chemical Formula 1,
X is halogen; and
n is an integer of 1 to 3.

11. The pellicle of claim 10, wherein a molar ratio of metal: silicon in the metal silicide capping layer is 1:0.2 to 6.
